(19) United States
(12) Patent Application Publication
(10) Pub. No.: US 2017/0155005 A1
(43) Pub. Date: Jun. 1, 2017

(54) SELENIZATION/SULFURIZATION PROCESS APPARATUS FOR USE WITH SINGLE-PIECE GLASS SUBSTRATE

(71) Applicant: NATIONAL CHUNG SHAN INSTITUTE OF SCIENCE AND TECHNOLOGY, Taoyuan City (TW)

(72) Inventors: WEN-CHUEH PAN, TAOYUAN CITY (TW); YIH-HSING WANG, TAOYUAN CITY (TW); MING-JUNE LIN, TAOYUAN CITY (TW); JEN-CHIEH LI, TAOYUAN CITY (TW); SHIH-SHAN WEI, TAOYUAN CITY (TW); TIEN-FU WU, TAOYUAN CITY (TW); TSAN-TUNG CHEN, TAOYUAN CITY (TW)

(21) Appl. No.: 14/955,360

(22) Filed: Dec. 1, 2015

(51) Int. Cl. H01L 31/032; H01L 31/18

(52) U.S. Cl. CPC H01L 31/0322; H01L 31/18

(57) ABSTRACT

A selenization/sulfurization process apparatus for use with a single-piece glass substrate is characterized by two chambers for heating up a glass substrate quickly and performing selenization/sulfurization on the glass substrate to not only prevent the glass substrate from staying at a soaking temperature of a softening point for a long period of time but also increase the thin-film selenization/sulfurization temperature according to the needs of the process to thereby reduce the duration of soaking selenization/sulfurization, save energy, and save time. The glass substrate undergoes reciprocating motion in the chambers to not only attain uniform temperature throughout the glass substrate but also distribute a selenization/sulfurization gas across the glass substrate uniformly during the selenization/sulfurization operation. The recycled liquid selenium/sulfur and inert gas are reusable to thereby reduce material costs.

### FIELD OF TECHNOLOGY

The present invention relates to selenization/sulfurization process apparatuses and more particularly to a selenization/sulfurization process apparatus for use with a single-piece glass substrate.

### BACKGROUND

Conventional solar cells with copper-indium-gallium-selenium (Cu/In/Ga/Se, CIGS) thin-film are made from direct bandgap semiconductor materials, with bandgap of 1.04 eV through 1.68 eV, and feature a very high optical absorption coefficient, a wide optical absorption range and high stability of long-term illumination, and a high possibility potential to achieve low material and manufacturing costs and exhibit satisfactory conversion efficiency. Hence, CIGS solar cells are presently the most promising solar cells.

Major conventional technologies applicable to the manufacturing of CIGS solar cells are mostly based on vacuum processes, including Cu/In/Ga precursor sputtering deposition then selenization and 3 stages co-evaporation process. In this regard, sputtering selenization process is currently the main mass production method in CIGS solar cell market. There are two types of sputtering selenization processes. One of the two types of sputtering selenization requires a high-temperature furnace and involves introducing H₂Se into closed vacuum to undergo high-temperature selenization, wherein multiple pieces of substrates are placed in a high-temperature furnace in each instance on condition that a precursor layer is disposed on the substrate surface. This type of sputtering selenization entails creating vacuum, introducing a gas, heating, soaking, lowering the temperature to room temperature, and discharging the gas, in a cyclical course, thereby taking much time (up to 10 hours). However, the multiple-piece process is unlikely to attain consistent uniformity but consumes much power and much pricey materials as well as incurs high costs. Another type of sputtering selenization is based on rapid thermal processing (RTP) and further divided into two categories. One category involves depositing a selenium thin-film on a substrate to function as a portion of a precusor layer and then performing rapid selenization by continuous temperature raising/soaking/temperature lowering and internal delivery. Alternatively, rapid selenization carried out by temperature raising/soaking/temperature lowering takes place in consecutive chambers which can be opened/insulated. The other category involves performing rapid selenization at selenium vapor state (cracking selenium) in the presence of a combination of a selenium thin-film and a precusor layer or in the presence of a precusor layer free of any selenium thin-film.

Manufacturing copper-indium-gallium-selenium-sulfur (CIGSS) thin-film solar cells on a soda-lime glass substrate requires producing a CIG (copper-indium-gallium) precursor by vacuum sputtering and producing a CIGSS absorption layer by a combination of a rapid thermal processing (RTP) process and the selenization/sulfurization technique to thereby advantageously render the manufacturing process high-quality, speedy and conducive to large-area production. Regarding to the design of a RTP selenization process, the stress (tensile or compressive stress) between the layers and the designed structures (single layer or multi-layer) depend on crystal orientation (amorphous or polycrystalline) of the Cu—In—Ga precusor film. In this regard, the design of a system in its entirety calls for the following considerations: (1) selenization/sulfurization temperature; (2) raising rate of the temperature and lowering rate of the temperature; (3) selenization/sulfurization duration and temperature distribution in each stage; (4) selenium/sulfur cracking module design; (5) high-temperature uniformity over entire glass substrate design; (6) chamber airtight and glass substrate moves smoothly oscillation in chamber and transfer quickly between two chambers; (7) ways of distributing selenium/sulfur atmosphere uniformly; and (8) selenium/sulfur pollution prevention and recycling mechanism. The aforesaid considerations are crucial factors in designing a system in its entirety, wherein rapid selenization occurs in selenium vapor state or rapid selenization occurs in selenium vapor state with a selenium evaporation film precursor.

Techniques and methods for manufacturing CIGS solar cells abound. However, the prior art has not yet successfully disclosed any process that meets both the demand for cost-effectiveness and the demand for high efficiency. In this regard, the major bottleneck lingers because stable technology about a large-area CIGS solar cell process remains undeveloped. Main issues pertaining to the process apparatus include: uneven irradiation heat during the process carried out with a large-area glass substrate; uniform distribution of selenium vapor; selenium vapor recycling; and deformation of a glass substrate during a high-temperature process. U.S. Pat. No. 5,578,503 discloses that a process is performed at a heating speed to increase the temperature by at least 10° C. per second to thereby prevent uneven distribution of thin-film surface tension which might otherwise be caused by liquefied element selenium in the course of selenization and the resultant solar cell conversion efficiency deterioration arising from poor crystallization. However, the glass substrate is likely to break apart during the process when a large-area glass substrate is heated up at a heating speed to increase the temperature by at least 10° C. per second. US 2010/0226629A1 discloses a way of preventing selenium contamination during a continuous selenization mass production process, but US 2010/0226629A1 fails to address an issue, that is, the uniform heating and recycling of selenium.

Accordingly, it is imperative to provide a selenization/sulfurization process apparatus for use with a glass substrate, so as to overcome the aforesaid drawbacks of the prior art.

### SUMMARY

It is an objective of the present invention to provide a selenization/sulfurization process apparatus capable of heating a single-piece glass substrate uniformly and performing selenization/sulfurization thereon uniformly.

Another objective of the present invention is to provide a selenization/sulfurization process apparatus for replacing selenization or sulfurization of toxic H₂Se or H₂S in a vacuum environment with cracking selenium or mixing sulfur with an inert gas in a near-atmospheric pressure environment.

Yet another objective of the present invention is to provide a selenization/sulfurization process apparatus capable of recycling and thus reusing excess selenium vapor or sulfur vapor in a process to thereby reduce material costs.

In order to achieve the above and other objectives, the present invention provides a selenization/sulfurization process apparatus for use with a glass substrate, comprising a first chamber, a first hot roller heating module, a first heater, a second chamber, a second hot roller heating module, a second heater, a gas uniform distribution module, a gas recycling module, an interface channel and a temperature measuring device. The first chamber has a first gate and a second gate. The first gate and the second gate are positioned on the front side and back side of the first chamber, respectively. The first hot roller heating module is disposed in the first chamber and between the first gate and the second gate. The first heater is disposed in the first chamber and positioned on the top side and bottom side of the first hot roller heating module. The second chamber has a third gate disposed at the front side of the second chamber. The second hot roller heating module is disposed in the second chamber and positioned proximate to the third gate. The second heater is disposed in the second chamber and positioned on the top side and bottom side of the second hot roller heating module. The gas uniform distribution module is connected to the second chamber to thereby introduce a mixing gas into the second chamber. The gas recycling module is connected to the second chamber to recycle the gas in the second chamber. The interface channel is connected to the second gate of the first chamber and the third gate of the second chamber. The temperature measuring device is disposed in the interface channel.

In an embodiment of the present invention, the first hot roller heating module has a plurality of first heating rollers each of which has therein a first roller heating unit.

In an embodiment of the present invention, the first heating rollers are made of graphite, silicon oxide ceramic, zirconium oxide ceramic, quartz or Inconel alloy.

In an embodiment of the present invention, the second hot roller heating module has a plurality of second heating rollers, and each second heating roller has therein a second roller heating unit.

In an embodiment of the present invention, the second heating rollers are made of graphite, silicon oxide ceramic, zirconium oxide ceramic, quartz or Inconel alloy.

In an embodiment of the present invention, the gas uniform distribution module comprises a vapor producing unit, an inert gas control unit, a gas mixing unit with a selenium vapor discharge control unit, a mixed gas cracking heating unit and a mixed gas distributing unit. The vapor producing unit produces selenium vapor or sulfur vapor and controls the output level of the selenium vapor or sulfur vapor by pressure adjustment. The inert gas control unit controls the output level of the inert gas. The mixing gas is mixed in the selenium vapor producing unit. The mixed gas cracking heating unit is connected to the gas mixing unit. The mixed gas distributing unit is connected to the gas cracking heating unit to distribute the gas uniformly through the channel to the nozzles onto the glass substrate in the second chamber.

In an embodiment of the present invention, the gas recycling module comprises a gas drawing unit, a condensation unit and a collecting unit. The gas drawing unit is connected to the second chamber via a gas drawing channel to draw out the gas from the second chamber. The condensation unit is connected to the gas drawing unit to separate the vapor and inert gas drawn out by the gas drawing unit. The collecting unit is connected to the condensation unit to collect the vapor and inert gas thus separated.

In an embodiment of the present invention, the first heater comprises a plurality of heating lamps.

In an embodiment of the present invention, the second heater comprises a plurality of heating lamps and a plurality of heating temperature equalizing plates.

In an embodiment of the present invention, the selenization or sulfurization process apparatus further comprises a first thermal insulation pad disposed on the inner wall of the first chamber.

In an embodiment of the present invention, the selenization or sulfurization process apparatus further comprises a second thermal insulation pad disposed on the inner wall of the second chamber.

In an embodiment of the present invention, the temperature measuring device is of non-contact style.

In an embodiment of the present invention, the selenization or sulfurization process apparatus further comprises a fourth gate disposed at the back end of the second chamber.

Hence, the selenization or sulfurization process apparatus of the present invention is characterized by two chambers for heating up a glass substrate quickly and performing selenization or sulfurization on the glass substrate to not only prevent the glass substrate from staying at a soaking temperature of a softening point for a long period of time but also increase the thin-film selenization/sulfurization temperature according to the needs of the process to thereby reduce the duration of soaking selenization or sulfurization process, save energy, and save time. The glass substrate undergoes reciprocating motion in the chambers to not only attain uniform temperature throughout the glass substrate but also distribute a selenization/sulfurization gas across the glass substrate uniformly during the selenization/sulfurization process. The recycled liquid selenium/sulfur and inert gas are reusable to thereby cut material costs.

### BRIEF DESCRIPTION

Objectives, features, and advantages of the present invention are hereunder illustrated with specific embodiments in conjunction with the accompanying drawings, in which:

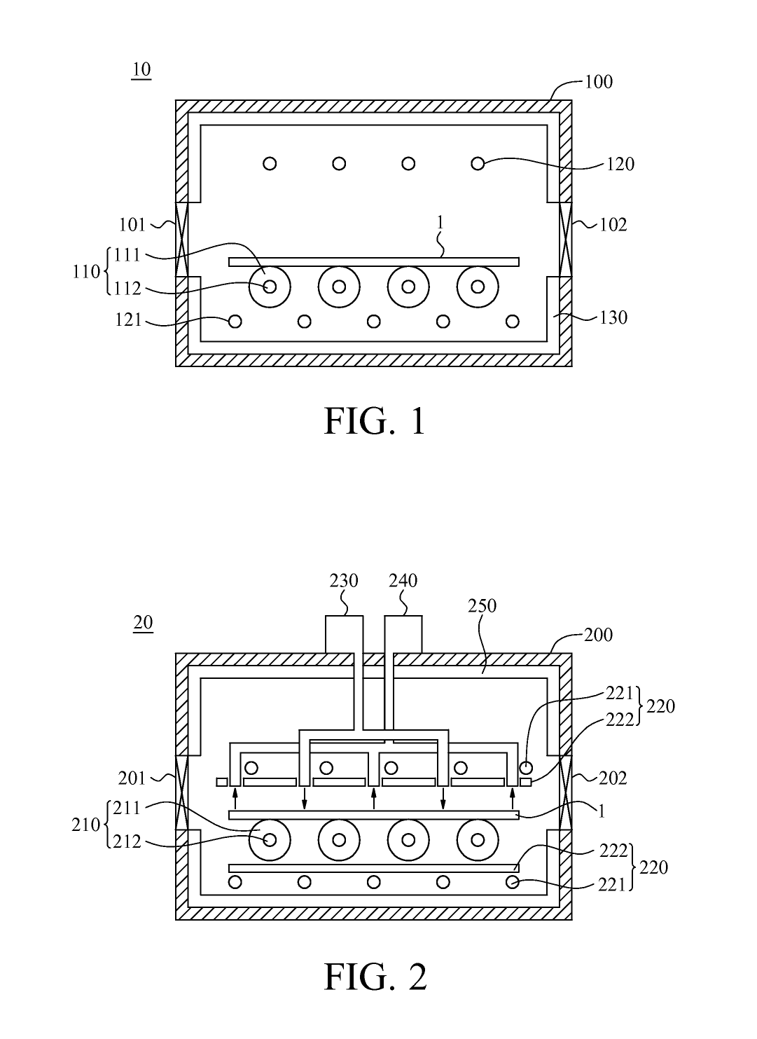

FIG. 1 is a schematic view of a rapid thermal processing device in an embodiment of the present invention;

FIG. 2 is a schematic view of a selenization or sulfurization soaking device in an embodiment of the present invention;

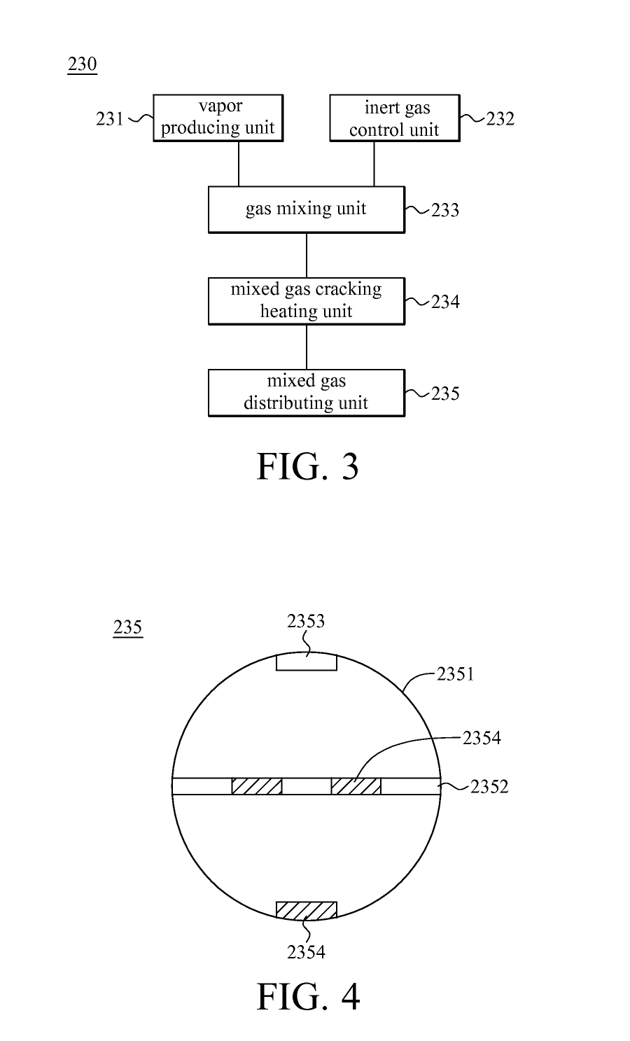

FIG. 3 is a function block diagram of a gas uniform distribution module in an embodiment of the present invention;

FIG. 4 is a schematic view of a mixed gas distributing unit in an embodiment of the present invention;

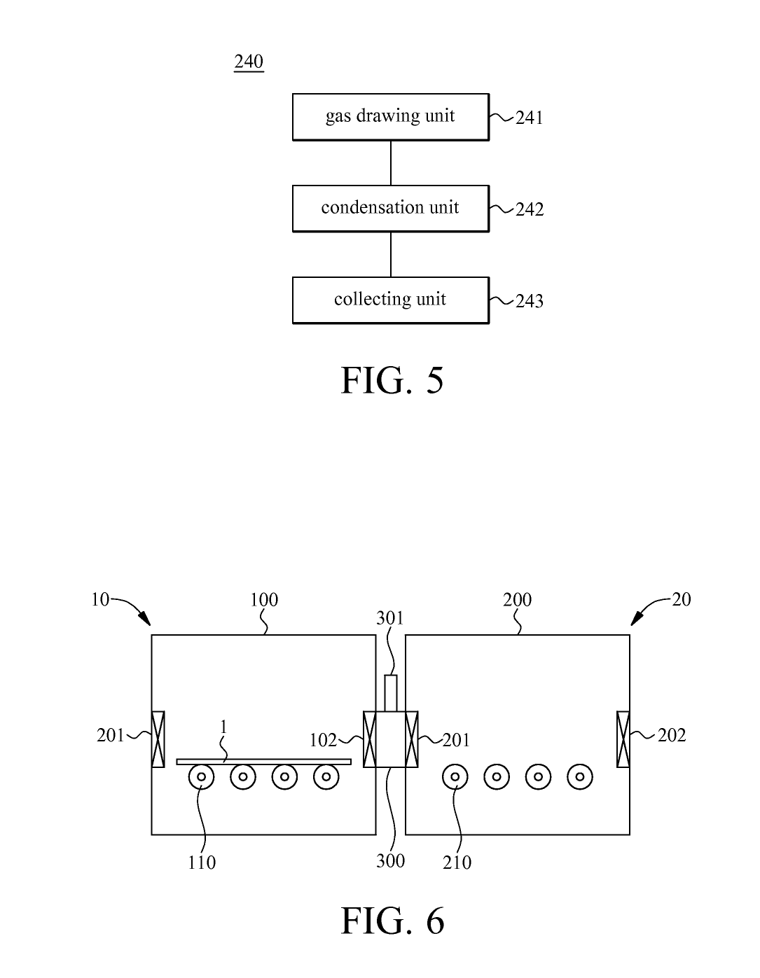

FIG. 5 is a function block diagram of a gas recycling module in an embodiment of the present invention; and

FIG. 6 is a schematic view of the rapid thermal processing device and the selenization/sulfurization soaking device coupled together in an embodiment of the present invention.

### DETAILED DESCRIPTION

Referring to FIG. 1, there is shown a schematic view of a rapid thermal processing (RTP) device 10 in an embodiment of the present invention. The rapid thermal processing device 10 raises the temperature of a glass substrate 1 uniformly and quickly with a view to providing a device capable of heating up a glass substrate at a speed, say 10° C./s, switching the glass substrate quickly, and allowing the glass substrate to undergo reciprocating motion. The rapid thermal processing device 10 has a first chamber 100, a first hot roller heating module 110 and two first heaters 120, 121.

The first chamber 100 has a first gate 101 and a second gate 102 which open or shut movably. The first gate 101 and the second gate 102 are disposed on the front side and back side of the first chamber 100, respectively. The first hot roller heating module 110 is disposed in the first chamber 100 and positioned between the first gate 101 and the second gate 102. The first heaters 120, 121 are disposed in the first chamber 100. The first heater 120 is disposed on the top side of the first hot roller heating module 110. The first heater 121 is disposed on the bottom side of the first hot roller heating module 110.

During the process, the rapid thermal processing device 10 enters a vacuum state with a vacuum pump (not shown) to insulate itself from the outside and thus form an airtight space by the first chamber 100, the first gate 101 and the second gate 102. The vacuum state is a low degree of vacuum state. The glass substrate 1 moves into and out of the first chamber 100 through the first gate 101 and the second gate 102.

During the process, the glass substrate 1 is placed on the first hot roller heating module 110, such that the first hot roller heating module 110 drives the glass substrate 1 to undergo reciprocating motion repeatedly. The first hot roller heating module 110 has a plurality of first heating rollers 111, and a first roller heating unit 112 is disposed in each first heating roller 111. The first roller heating units 112 heat up the first heating rollers 111 uniformly, such that the temperature of the contact surfaces of the first heating rollers 111 in contact with the glass substrate 1 and the temperature of the glass substrate 1 are kept within a specific range of temperature. Furthermore, the first heating rollers 111 are made from materials which are tolerant to high-temperature selenization/sulfurization process, such as graphite, silicon oxide ceramic, zirconium oxide ceramic, quartz or Inconel alloy, and outer surfaces of the first heating rollers 111 are made of a plasma-clad ceramic thin-film to increase their surface friction coefficient and maintain a certain thermal conductivity coefficient.

The first heaters 120, 121 heat up the glass substrate 1 and the CIGS thin-film (not shown) on the upper surface of the glass substrate 1. In this embodiment, the first heaters 120, 121 are heating lamps, as heating lamps have a high heating speed. Selectively, specific heating lamps are employed to emit light rays with a wavelength which matches the wavelength of the heat energy absorbed by the CIGS thin-film on the upper surface of the glass substrate 1 and the glass substrate 1, thereby increasing the heating efficiency.

To contain the heat in the first chamber 100 and thus maintain the temperature in the first chamber 100, a thermal insulation pad 130 (such as a graphite blanket) is disposed on the inner wall of the first chamber 100.

Referring to FIG. 2, there is shown a schematic view of a selenization or sulfurization soaking device 20 in an embodiment of the present invention. The selenization/sulfurization soaking device 20 performs a selenization or sulfurization process on the glass substrate 1 uniformly so as to perform high-temperature soaking selenization or sulfurization process on the glass substrate, moving the glass substrate, and switch the rolling direction of the hot roller to effectuate the reciprocating motion of the glass substrate. The selenization or sulfurization soaking device 20 comprises a second chamber 200, a second hot roller heating module 210, a second heating module 220, a gas uniform distribution module 230 and a gas recycling module 240.

The second chamber 200 has a third gate 201 which opens or shuts movably and a fourth gate 202 provided as needed. The second hot roller heating module 210 is disposed in the second chamber 200 and positioned between the third gate 201 and the fourth gate 202. The second heater 220 is disposed in the second chamber 200 and positioned on the top side and bottom side of the second hot roller heating module 210.

During a process operation, like the rapid thermal processing device 10, the selenization/sulfurization soaking device 20 is insulated from the outside by the second chamber 200, the third gate 201 and the fourth gate 202 to form an airtight space with a low degree of vacuum state. The glass substrate 1 moves into or out of the second chamber 200 via the third gate 201 and the fourth gate 202.

During a process operation, the glass substrate 1 is placed on the second hot roller heating module 210. The second hot roller heating module 210 drives the glass substrate 1 to undergo reciprocating motion repeatedly. Like the first hot roller heating module 110, the second hot roller heating module 210 has a plurality of second heating rollers 211. Each second heating roller 211 has therein a second roller heating unit 212. Furthermore, the second heating rollers 211 are made from materials which are tolerant to high-temperature selenization/sulfurization process, such as graphite, silicon oxide ceramic, zirconium oxide ceramic, quartz or Inconel alloy, and outer surfaces of the second heating rollers 211 are made of a plasma-clad ceramic thin-film to increase their surface friction coefficient and maintain a certain thermal conductivity coefficient.

The second heating module 220 heats up the glass substrate 1 and the CIGS thin-film (not shown) on the upper surface of the glass substrate 1. In this embodiment, the second heater 220 comprises a plurality of heating lamps 221 and a plurality of heating temperature equalizing plates 222. The heating lamps 221 heat up the heating temperature equalizing boards 222 to the temperature required for the process. Furthermore, a radiation reflector (not shown) is disposed beside the second chamber 200 which houses the glass substrate 1 to compensate for low borderline temperature of the glass substrate. Openings are disposed on the disconnected heating temperature equalizing plates 222 in the second chamber 200 to function as inlets and outlets for the gas of the gas uniform distribution module 230 and the gas recycling module 240.

To contain the heat in the second chamber 200 and thus maintain the temperature in the second chamber 200, a thermal insulation pad 250 (such as a graphite blanket) is disposed on the inner wall of the second chamber 100.

Referring to FIG. 3, there is shown a function block diagram of a gas uniform distribution module 230 in an embodiment of the present invention. The gas uniform distribution module 230 comprises a vapor producing unit 231, an inert gas control unit 232, a gas mixing unit 233, a mixed gas cracking heating unit 234 and a mixed gas distributing unit 235.

The vapor producing unit 231 produces selenium vapor or sulfur vapor during the selenization or sulfurization process and controls the output level of the selenium vapor or sulfur vapor by pressure adjustment. The inert gas control unit 232 controls the output level of the inert gas by pressure and flow rate adjustment. The gas mixing unit 233 is connected to the vapor producing unit 231 and the inert gas control unit 232 to thereby mix and output the vapor produced by the vapor producing unit 231 and the inert gas output by the inert gas control unit 232. The mixed gas cracking heating unit 234 is connected to the gas mixing unit 233 to thereby produce a mixed gas attributed to selenium vapor or sulfur vapor and capable of high-temperature cracking. Unlike a conventional selenization/sulfurization process, the selenization/sulfurization process of the present invention not only involves replacing selenization or sulfurization of toxic H₂Se or H₂S in a vacuum environment with cracking selenium or mixing sulfur with an inert gas in a near-atmospheric pressure environment to render the process safe, but also has the following technical features: the mixed gas distributing unit 235 is connected to the gas cracking heating unit 234 and the second chamber 200; the gas output by the mixed gas cracking heating unit 234 is uniformly distributed in the second chamber 200, such that a mixed gas attributed to selenium vapor or sulfur vapor and capable of high-temperature cracking is distributed across the glass substrate 1 at a uniform flow rate; the shape and size of the orifices of the mixed gas distributing unit 235 are determined by CFD computation and analysis, such that the gas distribution perpendicular to the direction of the motion of the glass substrate 1 meets process requirements.

Referring to FIG. 4, there is shown a schematic view of the mixed gas distributing unit 235 in an embodiment of the present invention. The mixed gas distributing unit 235 is formed by coupling together a plate 2352 and two halves of a round pipe 2351. A main aperture 2353 is disposed on top of the pipe 2351 and connected to the mixed gas cracking heating unit 234. The round pipe 2351 has therein the plate 2352. A plurality of through gas-emitting holes 2354 is disposed at the lower end of the round pipe 2351 and the flat board 2352, such that a mixture of selenium/sulfur vapor and an inert gas passes the through gas-emitting holes 2354 to distribute uniformly across the glass substrate 1.

Referring to FIG. 5, there is shown a function block diagram of a gas recycling module 240 in an embodiment of the present invention. The gas recycling module 240 comprises a gas drawing unit 241, a condensation unit 242 and a collecting unit 243.

The gas drawing unit 241 connects with the second chamber 200 via a gas drawing channel (not shown) to thereby draw the excess selenium vapor, sulfur vapor and inert gas out of the second chamber 200 during the process. The condensation unit 242 connects with the gas drawing unit 241 to thereby solidify, by condensation, the selenium/sulfur vapor and inert gas drawn into the gas drawing unit 241. The solid-state selenium/sulfur and inert gas are recycled and reused by a mechanism for separating a gas phase and a solid phase. The collecting unit 243 connects with the condensation unit 242 to thereby collect solid-state selenium and inert gas thus separated, so as to reuse the recycled solid-state selenium and inert gas, thereby reducing material costs.

Referring to FIG. 6, there is shown a schematic view of the rapid thermal processing device and the selenization/sulfurization soaking device coupled together in an embodiment of the present invention. FIG. 6 illustrates definitely the relation between the rapid thermal processing device 10 and the selenization/sulfurization soaking device 20, and thus FIG. 6 shows part of the elements of the present invention. See FIG. 1 through FIG. 5 for the other elements of the present invention.

The first chamber 100 and the second chamber 200 are connected by an interface channel 300. The two ends of the interface channel 300 are connected to the second gate 102 of the first chamber 100 and the third gate 201 of the second chamber 200, respectively, such that the interface channel 300 functions as an interface between the first chamber 100 and the second chamber 200. A temperature measuring device 301 is disposed between the first chamber 100 and the second chamber 200 and positioned on the interface channel 300. The temperature measuring device 301 is of non-contact style. The temperature measuring device 301 measures, in real time, the temperature of a thin-film of the glass substrate 1 while passing through the interface channel 300.

In general, the selenization/sulfurization process comprises the following steps: introducing the glass substrate 1 into the first chamber 100 by the first hot roller heating module 110 as soon as the first gate 101 of the first chamber 100 opens; shutting the first through fourth gates 101, 102, 201 and 202; starting a vacuum ventilation system; and starting a heating system (such as the first hot roller heating module 110 and the first heater 120 shown in FIG. 1 and the second hot roller heating module 210 and the second heater 220 shown in FIG. 2) of the first chamber 100 and the second chamber 200 when the first chamber 100 and the second chamber 200 reach a low to median degree of vacuum state, say 10−2 torr, respectively. After the glass substrate 1 has been placed on the first hot roller heating module 110 in the first chamber 100 with a low to median degree of vacuum, the first roller heating unit 112 disposed in the first heating rollers 111 begin to heat up the first heating rollers 111 while the first heater 120 is heating up the glass substrate 1 quickly; meanwhile, the first heater 120 beneath the first hot roller heating module 110 heats up the first heating rollers 111 such that the difference between the surface temperature of the first heating rollers 111 and the temperature of the glass substrate 1 is kept within a specific range.

At this point in time, the heating lamps 221 of the second heater 220 of the second chamber 200 has heated up the heating temperature equalizing plates 222, whereas the second roller heating unit 212 disposed in the second heating rollers 211 of the second hot roller heating module 210 is heating up the second heating rollers 211. Also, the heating temperature equalizing plates 222 beneath the second hot roller heating module 210 are operating in conjunction with the second heating rollers 211, such that the difference between the surface temperature of the second heating rollers 211 and the temperature of the glass substrate 1 is kept within a specific range.

By the time when the temperature in the first chamber 100 has risen to a specific temperature, both the second gate 102 of the first chamber 100 and the third gate 201 of the second chamber 200 open; meanwhile, the temperatures of the first hot roller heating module 110 in the first chamber 100, the second hot roller heating module 210 in the second chamber 200, the glass substrate 1, the heating temperature equalizing plates 222 in the second chamber 200 will be maintained within a specific temperature range. Afterward, the first hot roller heating module 110 in the first chamber 100 conveys the glass substrate 1 to the second chamber 200 quickly through the interface channel 300, and then the glass substrate 1 is received by the second hot roller heating module 210 of the second chamber 200, such that the glass substrate 1 undergoes reciprocating motion in the second chamber 200. The second gate 102 of the first chamber 100 and the third gate 201 of the second chamber 200 shut so as to form their respective airtight spaces as soon as the glass substrate 1 is conveyed to the second chamber 200. In this regard, if the process is a continuous process, the first chamber 100 can heat up the glass substrate 1 quickly in the next instance. As mentioned before, the soaking selenization process which takes place in the second chamber 200 involves forming a CIGS thin-film by selenization/sulfurization performed on a thin-film on the glass substrate 1 at high temperature and in the presence of a mixture of an inert gas and selenium/sulfur vapor produced by the gas uniform distribution module 230 with a controllable yield.

If the process is a multi-stage soaking temperature selenization/sulfurization process, after undergoing first-stage soaking temperature selenization/sulfurization in the second chamber 200, the glass substrate 1 is sent back to the first chamber 100 in the aforesaid manner to undergo second-stage rapid thermal processing, and then the glass substrate 1 is conveyed to the second chamber 200 as soon as the temperature reaches the process temperature specified for the second stage to continue with second-stage soaking selenization/sulfurization process. Alternatively, upon completion of the first-stage selenization/sulfurization, the glass substrate 1 is conveyed from the second chamber 200 to another chamber (not shown), such as another selenization/sulfurization process apparatus, connected to the fourth gate 202 of the second chamber 200 to continue with rapid thermal processing and selenization/sulfurization in the subsequent stage.

Therefore, the selenization/sulfurization process apparatus of the present invention is characterized by two chambers for heating up a glass substrate quickly and performing selenization/sulfurization on the glass substrate to not only prevent the glass substrate from staying at a soaking temperature of a softening point for a long period of time but also increase the thin-film selenization/sulfurization temperature according to the needs of the process to thereby reduce the duration of soaking selenization/sulfurization, save energy, and save time. The glass substrate undergoes reciprocating motion in the chambers to not only attain uniform temperature throughout the glass substrate but also distribute a selenization/sulfurization gas across the glass substrate uniformly during the selenization/sulfurization operation. Furthermore, recycled liquid selenium/sulfur and inert gas can be reused to thereby reduce material costs.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A selenization/sulfurization process apparatus for use with a glass substrate, comprising:
a first chamber having a first gate and a second gate, wherein the first gate and the second gate are disposed on two unconnected sides of the first chamber, respectively;
a first hot roller heating module disposed in the first chamber and between the first gate and the second gate;
a first heater disposed in the first chamber and positioned on a top side and a bottom side of the first hot roller heating module;
a second chamber having a third gate and disposed beside the second chamber;
a second hot roller heating module disposed in the second chamber and positioned proximate to the third gate;
a second heater disposed in the second chamber and positioned on a top side and a bottom side of the second hot roller heating module;
a heating temperature equalizing plate disposed in the second chamber to allow the radiation heat from heating lamps to be distributed uniformly to the glass substrate;
a gas uniform distribution module connected to the second chamber to thereby introduce a gas into the second chamber;
a gas recycling module connected to the second chamber to thereby recycle the gas in the second chamber;
an interface channel connected to the first gate of the first chamber and the third gate of the second chamber, respectively; and
a non-contact temperature measuring device disposed in the interface channel.

2. The selenization/sulfurization process apparatus of claim 1, wherein the first hot roller heating module has a plurality of first heating rollers each having therein a first roller heating unit.

3. The selenization/sulfurization process apparatus of claim 2, wherein the first heating rollers are made of one of graphite, silicon oxide ceramic, zirconium oxide ceramic, quartz and Inconel.

4. The selenization/sulfurization process apparatus of claim 3, wherein outer surfaces of the first heating rollers are made of a plasma-clad ceramic thin-film.

5. The selenization/sulfurization process apparatus of claim 1, wherein the second hot roller heating module has a plurality of second heating rollers each having therein a second roller heating unit.

6. The selenization/sulfurization process apparatus of claim 5, wherein the second heating rollers are made of one of graphite, silicon oxide ceramic, zirconium oxide ceramic, quartz and Inconel.

7. The selenization/sulfurization process apparatus of claim 6, wherein outer surfaces of the second heating rollers are made of a plasma-clad ceramic thin-film.

8. The selenization/sulfurization process apparatus of claim 1, wherein the gas uniform distribution module comprises:
a vapor producing unit for producing one of selenium vapor and sulfur vapor and controlling an output level of the one of selenium vapor and sulfur vapor by pressure adjustment;
an inert gas control unit for controlling an output level of an inert gas;
a gas mixing unit connected to the vapor producing unit and the inert gas control unit to thereby mix and output the vapor produced by the vapor producing unit and the inert gas output by the inert gas control unit;
a mixed gas cracking heating unit connected to the gas mixing unit; and
a mixed gas distributing unit for connecting the gas cracking heating unit and the second chamber and distributing uniformly the gas output by the mixed gas cracking heating unit on the glass substrate in the second chamber.

9. The selenization/sulfurization process apparatus of claim 1, wherein the gas recycling module comprises:
a gas drawing unit connected to the second chamber via a gas drawing channel to thereby draw out the gas from the second chamber;
a condensation unit connected to the gas drawing unit to thereby separate the vapor and the inert gas drawn out by the gas drawing unit; and
a collecting unit connected to the condensation unit to collect the vapor and the inert gas thus separated.

10. The selenization/sulfurization process apparatus of claim 1, wherein the first heater comprises a plurality of heating lamps.

11. The selenization/sulfurization process apparatus of claim 1, wherein the second heater comprises a plurality of heating lamps and a plurality of heating temperature equalizing boards.

12. The selenization/sulfurization process apparatus of claim 1, further comprising a first thermal insulation pad disposed on an inner wall of the first chamber.

13. The selenization/sulfurization process apparatus of claim 1, further comprising a second thermal insulation pad disposed on an inner wall of the second chamber.

14. The selenization/sulfurization process apparatus of claim 1, wherein heating temperature equalizing plates made of graphite are disposed in the second chamber to allow the radiation heat from heating lamps to be distributed uniformly to the glass substrate.

15. The selenization/sulfurization process apparatus of claim 1, wherein mixed gases are distributed onto the surface of the glass substrate uniformly, a mixed gas distributing unit is formed by coupling together a plate and two halves of a round pipe, wherein a plurality of through gas-emitting holes is disposed at the lower end of the round pipe and the flat board, such that a mixture of selenium/sulfur vapor and an inert gas passes the through gas-emitting holes to distribute uniformly across the glass substrate.
